(19) United States
(12) Patent Application Publication
(10) Pub. No.: US 2017/0092637 A1
(43) Pub. Date: Mar. 30, 2017

(54) Semiconductor ESD Protection Device and Method

(71) Applicant: Infineon Technologies AG, Neubiberg (DE)

(72) Inventor: Winfried Bakalski, Muenchen (DE)

(21) Appl. No.: 14/871,007

(22) Filed: Sep. 30, 2015

(51) Int. Cl. H01L 27/02; H02H 9/04; H01L 27/06

(52) U.S. Cl. CPC H01L 27/0285; H01L 27/0629; H02H 9/04

(57) ABSTRACT

According to an embodiment, an electrostatic discharge (ESD) protection circuit includes a first transistor having a first source/drain coupled to a first input/output terminal, a second source/drain coupled to a first reference voltage terminal, and a gate coupled to a second reference voltage terminal. The ESD protection circuit further includes a direct current (DC) blocking circuit having a first input/output node coupled to the first input/output terminal, a second input/output node configured to be coupled to a useful circuit, and a third input/output node coupled a gate of the first transistor.

### TECHNICAL FIELD

An embodiment of the present disclosure relates generally to integrated circuits, semiconductor devices, and methods, and more particularly to an electrostatic discharge (ESD) protection device and a method of protecting an integrated circuit against electrostatic discharge.

### BACKGROUND

As electronic components of integrated circuits continue to become smaller, it has become easier to either completely destroy or otherwise impair the electronic components. In particular, many integrated circuits are highly susceptible to damage from the unintended discharge of static electricity, generally as a result of handling or from physical contact with another charged body. Electrostatic discharge (ESD) is the transfer of an electric charge between bodies at different electrostatic potentials or voltages, caused by direct contact, or induced by an electrostatic field. The discharge of static electricity has become a critical problem for the electronics industry.

Device failures that result from ESD events are not always immediately catastrophic or apparent. Often, the device is only slightly weakened but is less able to withstand normal operating stresses and, hence, may result in a reliability problem. Therefore, various ESD protection circuits should be included in the device to protect the various components.

When an ESD discharge occurs onto a transistor or other semiconductor element, the high voltage and current of the ESD pulse relative to the voltage- and current-sustaining capabilities of structures within the device can break down the transistor and potentially cause permanent damage. Consequently, circuits associated with input/output pads of an integrated circuit need to be protected from ESD pulses so that they are not damaged by such discharges.

### SUMMARY

According to an embodiment, an electrostatic discharge (ESD) protection circuit includes a first transistor having a first source/drain coupled to a first input/output terminal, a second source/drain coupled to a first reference voltage terminal, and a gate coupled to a second reference voltage terminal. The ESD protection circuit further includes a direct current (DC) blocking circuit having a first input/output node coupled to the first input/output terminal, a second input/output node configured to be coupled to a useful circuit, and a third input/output node coupled a gate of the first transistor.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an integrated circuit having an exemplary ESD protection circuit coupled to a useful circuit;

FIG. 2 illustrates an integrated circuit having an ESD protection circuit coupled to a useful circuit in accordance with some embodiments;

FIG. 3 illustrates an equivalent circuit diagram of an ESD protection circuit in accordance with some embodiments;

FIGS. 4 to 9 illustrate integrated circuits having ESD protection circuits coupled to respective useful circuits in accordance with some embodiments; and

FIG. 10 illustrates a flowchart of a method of operating an ESD protection circuit in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Description is made with respect to various embodiments in a specific context, namely integrated circuits, semiconductor devices, and methods, and more particularly to electrostatic discharge (ESD) protection devices and methods of protecting integrated circuits from ESD events. The integrated circuits are particularly vulnerable to ESD events in a switched-off state while handling such as, for example, during soldering components of the integrated circuits or during soldering the integrated circuits to a printed circuit board.

One of the issues with respect to implementing radio frequency (RF) circuits in a semiconductor process is providing a good RF environment in addition to ensuring adequate protection against ESD events. In some cases this may lead to a tradeoff between RF performance and ESD protection. For example, a resistance of the ESD device may add noise to the system and a capacitive loading of the ESD device may lead to attenuation of the RF signal and distortion due to non-linearity of semiconductor junctions that make up the ESD device. In embodiments of the present invention, an ESD device coupled to an RF input/output pin of an integrated circuit includes an N-type metal-oxide-semiconductor (NMOS) device having a source/drain connected to the RF input/output pin of the integrated circuit. The gate of this NMOS device is connected to a negative voltage generator, such as a charge pump, so that during operation of the integrated circuit, the RF input/output pin has an increased input range before the NMOS device turns on. However, when the integrated circuit is powered down or is not installed on a printed circuit board (PCB), the gate of the NMOS device assumes a potential of the ground pin so that that the NMOS device becomes conductive at a voltage level that preserves the circuitry coupled to the ESD device. In some embodiments, the RF input/output pin is capacitively coupled to the gate of the NMOS device, as well as to a useful circuit on the integrated circuit. While the various embodiments are described with reference to NMOS transistors, one of the ordinary skill in the art would appreciate that various embodiments such as those described herein may be also implemented using P-type metal-oxide-semiconductor (PMOS) transistors.

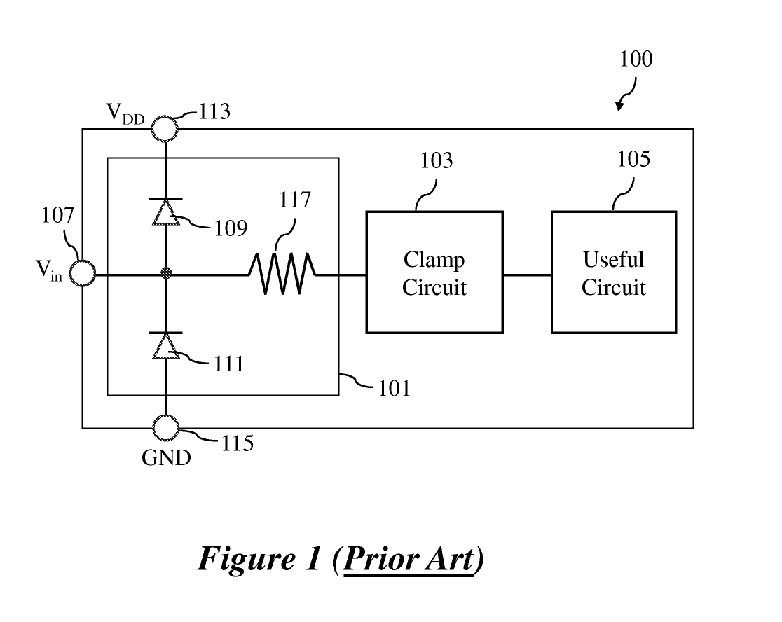

FIG. 1 illustrates an integrated circuit 100 including an exemplary ESD protection circuit 101 coupled to a useful circuit 105. The exemplary ESD protection circuit 101 is coupled between an input terminal 107 of the integrated circuit 100 and an input/output terminal of the useful circuit 105 and protects the useful circuit 105 from ESD events occurring at the input terminal 107 of the integrated circuit 100. In some embodiments, the useful circuit 105 may be a low noise amplifier (LNA), power amplifier (PA), a switch, a mixer, the like, or a combination thereof. The exemplary ESD protection circuit 101 includes ESD diodes 109 and 111, which are series coupled between terminals 113 and 115 of the integrated circuit 100. The terminal 113 is biased using a reference voltage V_{DD} and the terminal 115 is coupled to the ground. The exemplary ESD protection circuit 101 further includes a resistor 117 coupled between the input terminal 107 of the integrated circuit 100 and the input/output terminal of the useful circuit 105. In some embodiments, a resistance of the resistor 117 may be between about 100Ω and about 1 kΩ, such as about 500Ω. However, in some embodiment RF applications, the resistor 117 may be bypassed in exchange for reduced ESD protection.

The integrated circuit 100 may further include a second level clamp circuit 103 coupled between the exemplary ESD protection circuit 101 and the useful circuit 105. The exemplary ESD protection circuit 101 provides rough clamping and may clamp the input/output terminal of the useful circuit 105 at a higher voltage than tolerated by the useful circuit 105. In such an event, the second level clamp circuit 103 may further reduce a voltage at the input/output terminal of the useful circuit 105. For example, the second level clamp circuit 103 may include a transistor similar to a transistor of the useful circuit 105 in order to better protect circuits prone to damage at relatively low voltage levels.

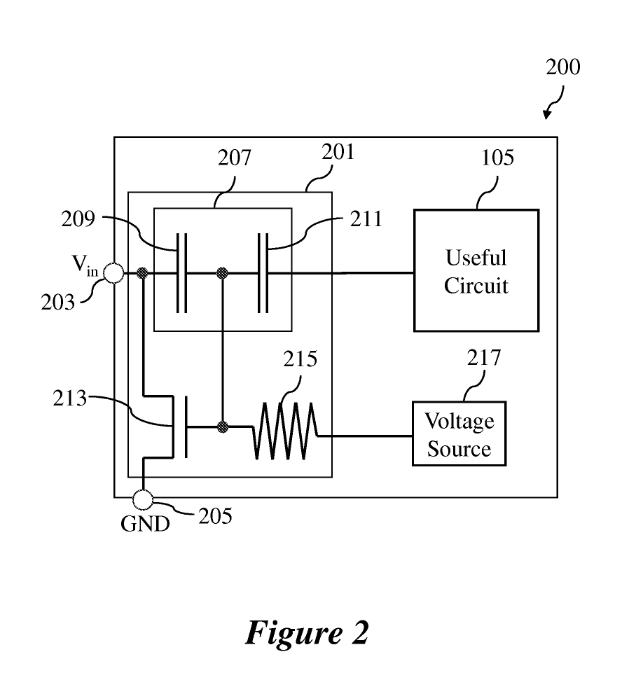

FIG. 2 illustrates an integrated circuit 200 including an embodiment ESD protection circuit 201 coupled to a useful circuit 105 in accordance with some embodiments. The ESD protection circuit 201 includes a transistor 213 having a source/drain terminal coupled to an input pin 203 of the integrated circuit 200. A gate of the transistor 213 is capacitively coupled to the input pin 203 via a capacitor 209, such that during an ESD event at which the voltage of input pin 203 rapidly increases, the gate of the transistor 213 is pulled high and the transistor 213 turns on to shunt an ESD current to the ground. In addition, the input pin 203 pin is capacitively coupled to the useful circuit 105 via capacitors 209 and 211. In some embodiments, the presence of the capacitors 209 and 211 and the transistor 213 is sufficient to provide adequate ESD protection without having an additional resistance in series with the useful circuit 105, thereby yielding improved noise performance.

During operation of the useful circuit 105, the gate of the transistor 219 is biased to a negative voltage using a voltage source 217 coupled to the gate of the transistor 219 through a resistor 215. By biasing the gate of the transistor 213 to a negative voltage, a larger input voltage swing may be tolerated at the input pin 203 of the integrated circuit without turning on the transistor 213, thereby increasing the linearity of the system. Moreover, in some embodiments in which a bulk silicon process is used to implement the transistor 213, a substrate of the integrated circuit and/or a bulk node of the transistor 213 may also be biased to a negative voltage respect to the ground in order to turn off a substrate/bulk diode of the transistor. By disabling the substrate/bulk diode, a non-linear capacitance of the substrate/bulk diode is reduced, thereby reducing non-linearities due to the non-linear capacitance of the substrate/bulk diode. In some embodiments, a silicon-on-insulator (SOI) process may be used to form the transistor 219 and to avoid biasing the substrate/bulk diode.

In some embodiments, the ESD protection circuit 201 includes a direct current (DC) blocking circuit 207 coupled between the input pin 203 and an input/output terminal of the useful circuit 105. The direct current (DC) blocking circuit 207 provides an AC signal path from the input pin 203 to useful circuit 105, as well as a coupling path to the gate of the transistor 213. In some embodiments, the DC blocking circuit 207 includes a first capacitor 209 connected to a second capacitor 211. In some embodiments, the first capacitor 209 and the second capacitor 211 are high quality factor (high-Q) metal-insulator-metal (MIM) capacitors, or the like. Capacitances of the first capacitor 209 and the second capacitor 211 are chosen depending on a frequency band used by the useful circuit 105. In some embodiments in which the frequency band of about 1 GHz is used, a capacitance of the first capacitor 209 is between about 1 pF and about 20 pF, such as about 2 pF, and a capacitance of the second capacitor 211 is between about 10 pF and about 100 pF, such as about 56 pF. In other embodiments in which the useful circuit 105 is configured for higher frequency applications, the capacitances of the first capacitor 209 and the second capacitor 211 are further reduced.

In some embodiments, the transistor 213 may be a field effect transistor (FET) such a MOS transistor formed using a bulk silicon process, a MOS transistor formed using a silicon-on-insulator (SOI) process, a high electron mobility transistor (HEMT) such as a GaAs-HEMT, or the like. In the illustrated embodiment, the transistor 213 is an NMOS transistor having a gate length L₁ between about 22 nm and about 500 nm, such as about 120 nm, a gate width W₁ between about 100 μm and about 1 mm, such as about 500 μm, a threshold voltage between about 0.2 V and about 0.5 V, and an ON-mode channel resistance Rₒₙ between about 0.5Ω and about 3Ω. In some embodiments, the ON-mode channel resistance Rₒₙ may tuned by changing, for example, the gate width W₁. In some embodiments in which the gate length L₁ is about 120 nm and the width W₁ is about 500 μm, the ON-mode channel resistance Rₒₙ is about 1Ω.

Referring further to FIG. 2, a first source/drain terminal of the transistor 213 is coupled to the input pin 203, a second source/drain terminal of the transistor 213 is coupled to a ground pin 205, and a gate of the transistor is coupled to a node of the DC blocking circuit 207 interposed between the first capacitor 209 and the second capacitor 211. In some embodiments, the gate of the transistor 213 is further coupled to the voltage source 217 through the resistor 215. In some embodiments, the voltage source 217 may be a charge pump implemented using circuits and systems known in the art. Alternatively, other voltage source circuits may be used. In some embodiments, a high ohmic resistance of the resistor 215 is between about 20 kΩ and about 1 MΩ, such as about 200 kΩ. In some embodiments, the resistance of the resistor 215 and the capacitances of the first capacitor 209 and the second capacitor 211 are chosen such that an RC time is low enough to adequately couple an ESD voltage to the gate of the transistor 213. In some embodiments, the voltage source 217 provides a reference voltage to the gate of the transistor 213 such that a polarity of the reference voltage is opposite to a polarity of a threshold voltage of the transistor 213. Accordingly, the reference voltage of the voltage source 217 turns the transistor 213 off. In some embodiments in which the transistor 213 is an NMOS transistor, the voltage source 217 provides a negative reference voltage between about −1 V and about −5 V, such as about −1.5 V used for an NMOS transistor formed using a typical 130 nm CMOS process.

During an ESD event a voltage pulse occurs at the input pin 203 of the integrated circuit 200. The voltage pulse may have the positive polarity or the negative polarity. The ESD protection circuit 201 protects the useful circuit 105 independent of the polarity of the voltage pulse. The voltage pulse starts to charge the first capacitor 209 and the second capacitor 211 of the DC blocking circuit 207 and affects a voltage seen by the gate of the transistor 213. In some embodiments in which the voltage pulse and the reference voltage of the voltage source 217 have a same polarity that is different from a polarity of the threshold voltage of the transistor 213, the transistor 213 remains turned off and the channel of the transistor 213 does not conduct. Instead, a substrate diode of the transistor 213 starts to conduct and clamps a voltage at the input/output terminal of the useful circuit 105 to a desired value that is lower than a damaging voltage value for the useful circuit 105. In some embodiments in which the voltage pulse and the threshold voltage of the transistor 213 have a same polarity that is different from a polarity of the reference voltage of the voltage source 217, the transistor 213 turns on as a gate voltage of the transistor 213 reaches the threshold voltage. In the On mode, the channel of the transistor 213 starts conducting and the input/output terminal of the useful circuit 105 is clamped to a desired voltage that is lower than a damaging voltage for the useful circuit 105. In some embodiment in which the transistor 213 is an NMOS transistor, the threshold voltage of the transistor 213 has the positive polarity and the reference voltage of the voltage source 217 has the negative polarity. Accordingly, the substrate diode of the transistor 213 conducts when a negative voltage pulse arrives at the input pin 203 of the integrated circuit 200, and the channel of the transistor 213 conducts when a positive voltage pulse arrives at the input pin 203 of the integrated circuit 200.

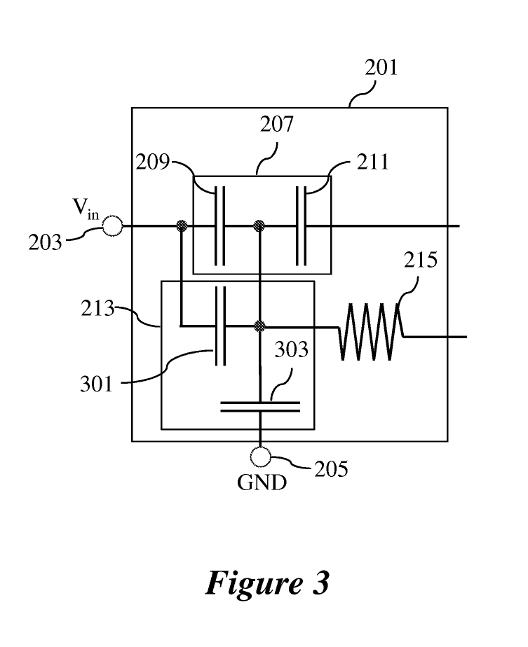

FIG. 3 illustrates an equivalent circuit diagram of the ESD protection circuit 201 in accordance with some embodiments. As described above in greater detail, in some embodiments, the gate of the transistor 213 is biased by the voltage source 217 (not shown in FIG. 3, see FIG. 2) to turn off the transistor 213. In the OFF mode, the transistor 213 can be represented by a capacitive circuit having a first capacitor 301 and a second capacitor 303. The first capacitor 301 and the second capacitor 303 represent the overlap capacitances of the transistor 213, such as a gate-source capacitance and a gate-drain capacitance of the transistor 213, which are high-Q capacitors. In some embodiments, a quality factor (Q) of the first capacitor 301 and the second capacitor 303 may be greater than a quality factor of the first capacitor 209 and the second capacitor 211 of the DC blocking circuit 207. In some embodiments, capacitances of the first capacitor 301 and the second capacitor 303 may be set in accordance with the gate width W1 of the transistor 213. In some embodiments in which the transistor 213 is an NMOS transistor with the gate length L1 of about 120 nm, the first capacitor 301 and the second capacitor 303 have a capacitance of about 0.92*W1 pF, where the gate width W1 of the transistor 213 is measured in millimeters. Alternatively, other gate lengths and widths may be used. In some embodiments, the ESD protection circuit 201 may cause impedance detuning and an RF matching circuit that includes, for example, inductors and capacitors may be used to match the input impedance to the useful circuit 105. In some embodiments, the use of high-Q components in the ESD protection circuit 201 allows for greater flexibility for the RF matching circuit without adversely affecting characteristics of the useful circuit 105. Furthermore, high-Q components may be less prone to introducing significant additional noise and insertion loss to the useful circuit 105. In addition to protecting the useful circuit 105 from ESD events, the ESD protection circuit 201 may also provide a DC free input for the useful circuit 105 such as, for example, an LNA.

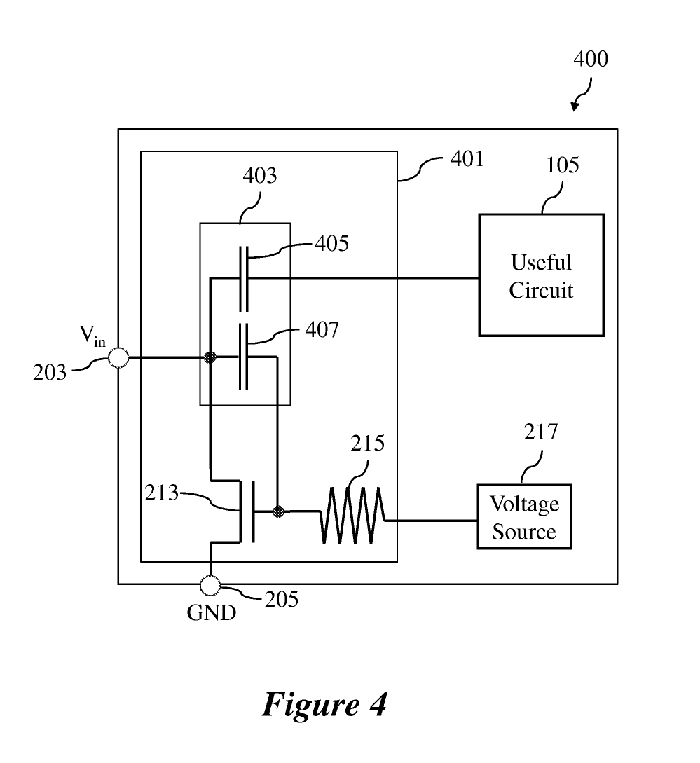

FIG. 4 illustrates an integrated circuit 400 having an embodiment ESD protection circuit 401 coupled to a useful circuit 105. The ESD protection circuit 401 differs from the ESD protection circuit 201 in that the useful circuit 105 is coupled to the input pin 203 directly by a first capacitor 405, and the gate of the transistor 213 is independently coupled to the input pin 203 by a second capacitor 407. In some embodiments, this provides a lower impedance connection to the useful circuit 105 and may reduce the total coupling capacitance in some cases. Capacitances of the first capacitor 405 and the second capacitor 407 are chosen depending on a frequency band used by the useful circuit 105. In some embodiments in which the frequency band of about 1 GHz is used, a capacitance of the first capacitor 405 is between about 1 pF and about 100 pF, such as about 10 pF, and a capacitance of the second capacitor 407 is between about 1 pF and about 10 pF, such as about 2 pF. In some embodiments, the second capacitor 407 may be omitted and the gate-overlap capacitance of the transistor 213 may be implemented as the second capacitor 407. The gate with of the transistor 213 is adjusted to tune the gate-overlap capacitance of the transistor 213 to a desired value. In other embodiments, the gate-overlap capacitance of an additional transistor (not shown) may be implemented as the second capacitor 407. In such embodiments, a gate with of the additional transistor is adjusted to tune the gate-overlap capacitance of the additional transistor to a desired value. During an ESD event, the ESD protection circuit 401 operates similar to the ESD protection circuit 201, described above with reference to FIG. 2.

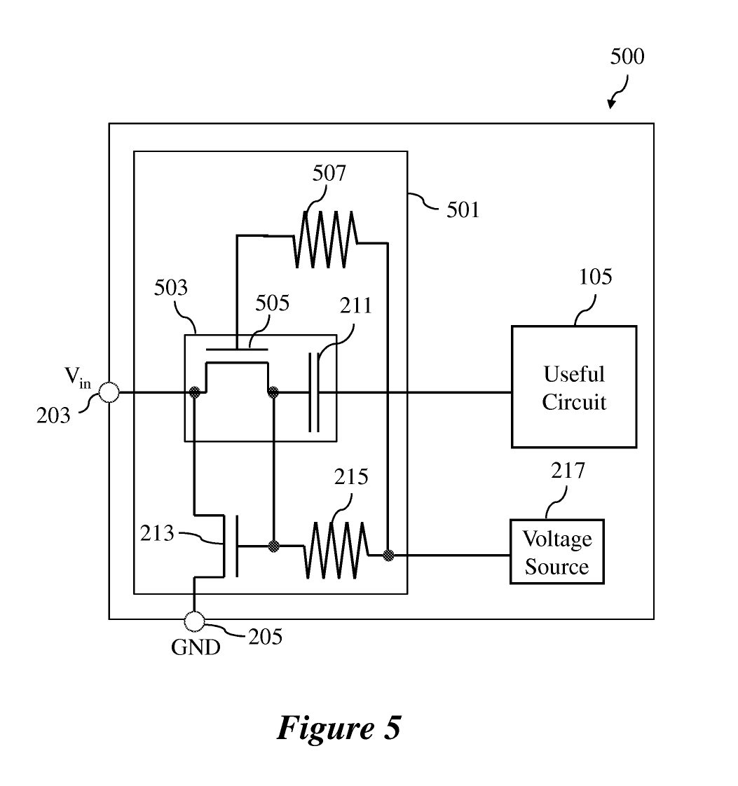

FIG. 5 illustrates an integrated circuit 500 having an embodiment ESD protection circuit 501 in which the capacitance coupled between the input pin 203 and the gate of transistor 213 is implemented using the gate-overlap capacitance of the transistor 505. As shown, a gate of the transistor 505 is coupled to the voltage source 217 via a resistor 507. When the transistor 505 is turned off via the voltage source 217, the dominant coupling across the source/drain terminals of the transistor 505 is via the gate-overlap capacitance because the channel of transistor 505 is turned off and the gate capacitance of the transistor 505 is coupled in series with the high impedance of the resistor 507.

In some embodiments, the transistor 505 may be a FET such a MOS transistor formed using a bulk silicon process, a MOS transistor formed using an SOI process, a HEMT such as a GaAs-HEMT, or the like. In some embodiments, an OFF-mode capacitance of the transistor 505 may be tuned by tuning a gate width W2 of the transistor 505. In some embodiments in which the transistor 505 is an NMOS transistor with a gate length L2 of about 120 nm, the overlap capacitances of the transistor 505, such as gate-drain and gate-source capacitances, have a capacitance of about 0.92*W2 pF, where the gate width W2 of the transistor 505 is measured in millimeters. For example, an NMOS transistor having a gate length of about 120 nm and a gate width of about 4400 μm may be used to replace the first capacitor 209 having a capacitance of about 2 pF. The ESD protection circuit 501 further includes a resistor 507 coupled between the gate of the transistor 505 and the voltage source 217. In some embodiments, a resistance of the resistor 507 is between about 20 kΩ and about 1 MΩ, such as about 200 kΩ. In some embodiments, a capacitor implemented using a gate-overlap capacitance of a transistor may have a greater capacitance per area than a MIM capacitor and may provide an additional substrate diode for negative ESD pulses. By implementing capacitors of ESD protection circuits using gate-overlap capacitances of transistors, the footprint of the ESD protection circuits may be further reduced. During an ESD event, the ESD protection circuit 501 operates similar to the ESD protection circuit 201, described above with reference to FIG. 2.

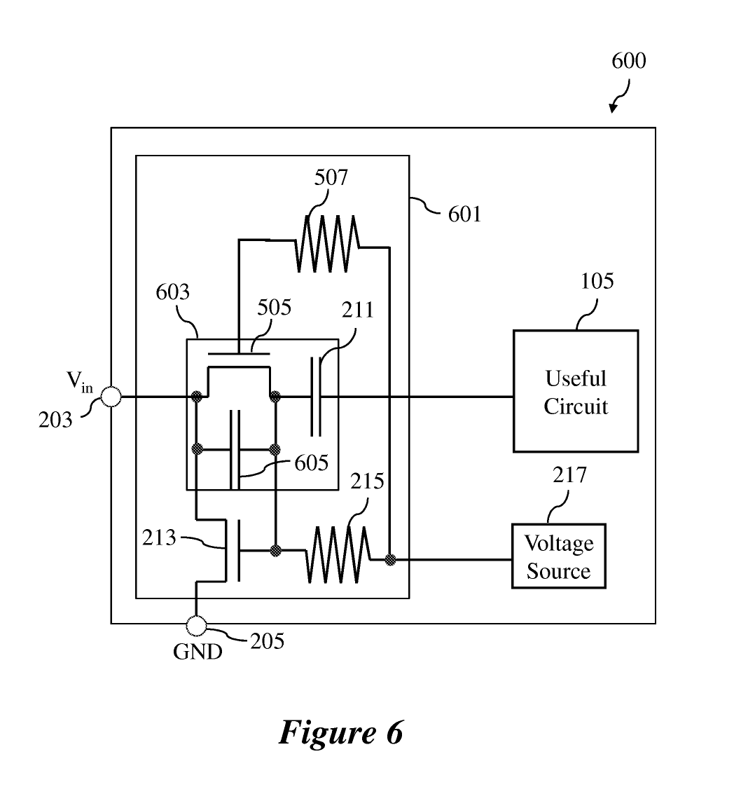

FIG. 6 illustrates an integrated circuit 600 having an embodiment ESD protection circuit 601 that is similar to the ESD protection circuit 501 shown in FIG. 5 with the addition of an extra capacitor 605 coupled in parallel with the source/drain terminals of the transistor 505. The capacitor 605 may be used to provide a partial impedance match to the useful circuit 105. In some embodiments, the use of the capacitor 605 may reduce the size or number of components used in an external impedance matching network and may allow for reducing a size of the transistor 505. Furthermore, the capacitor 605 implemented as a MIM capacitor may be stacked atop the transistor 505. This may allow for reduction of a footprint of the ESD protection circuit 601 and allow for better chip area usage. In some embodiments, a capacitance of the capacitor 605 is between about 1 pF and about 20 pF. During an ESD event, the ESD protection circuit 601 operates similar to the ESD protection circuit 201, described above with reference to FIG. 2, and the description is not repeated herein.

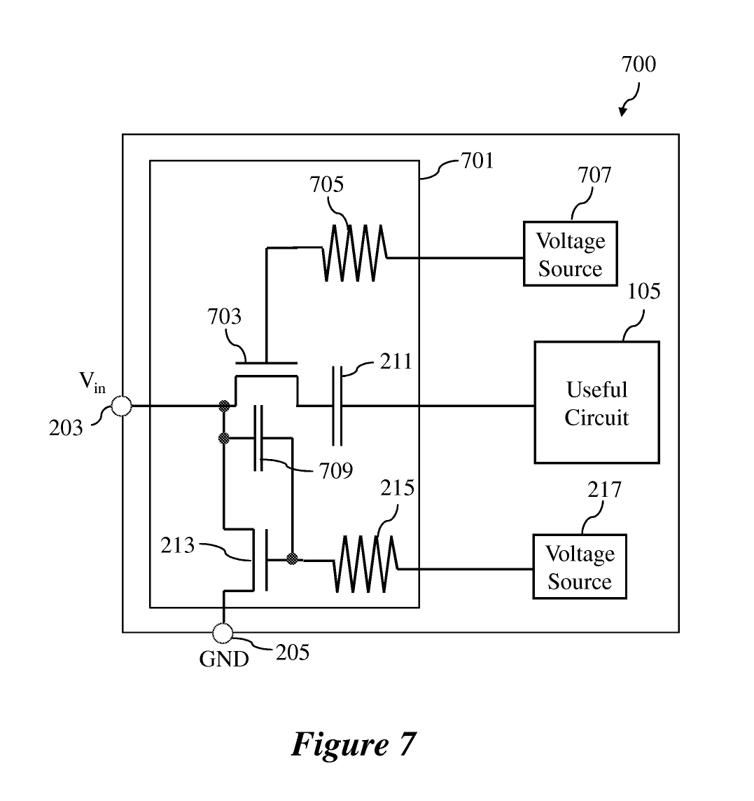

FIG. 7 illustrates an integrated circuit 700 having an embodiment ESD protection circuit 701 that includes a transistor 703 coupled in series with the capacitor 211 between the input pin 203 and the useful circuit 105 in addition to the transistor 213. In various embodiments, the transistor 703 provides an additional protection from ESD events and is operated in the ON mode by coupling a gate of the transistor 703 to a voltage source 707 that provides a voltage sufficient to turn-on transistor 703. Series resistor 705 is provided to reduce the effect of capacitive coupling of the gate capacitance of transistor 703. In some embodiments in which the transistor 703 is an NMOS transistor, the voltage source 707 provides a positive voltage between about 1.5 V and about 3 V to the gate of the transistor 703. The ESD protection circuit 701 further includes a capacitor 709 coupled between the input pin 203 and the gate of the transistor 213. However, in some embodiments, the capacitor 709 may be omitted and the gate-overlap capacitance of the transistor 213 may be used instead of the capacitor 709. In some embodiments in which the capacitor 709 is omitted, the transistor 213 is a symmetric transistor and an ESD pulse having a same polarity as the threshold voltage of the transistor 213 arrives at the input pin 203, the transistor 213 of the ESD protection circuit 701 clamps the input/output terminal of the useful circuit 105 at a voltage of about two times the threshold voltage of the transistor 213 at the earliest. In some embodiments, such a voltage may be larger than a voltage that is safely tolerated by the useful circuit 105. In such embodiments, the voltage source 707 provides a gate voltage to the transistor 703 such that a difference between the gate voltage of the transistor 703 and a voltage clamped by the transistor 213 (such as about two times the threshold voltage of the transistor 213) is less than a threshold voltage of the transistor 703. Accordingly, the transistor 703 turns off and the entire ESD pulse discharges through the transistor 213. In some embodiments, the ESD protection circuit 701 may be used as a functional RF switch in addition to being an ESD protection circuit.

Various embodiments described above have a single transistor (such the transistor 213 illustrated in FIG. 2), which operates in the OFF mode by applying a suitable reference voltage to a gate of the single transistor. For some applications, ESD protection circuits with higher clamping voltage may be required. For such applications, a single transistor may not provide a desired clamping voltage. As described below in greater detail, a stack of N transistors may be used to obtain a desired clamping voltage level.

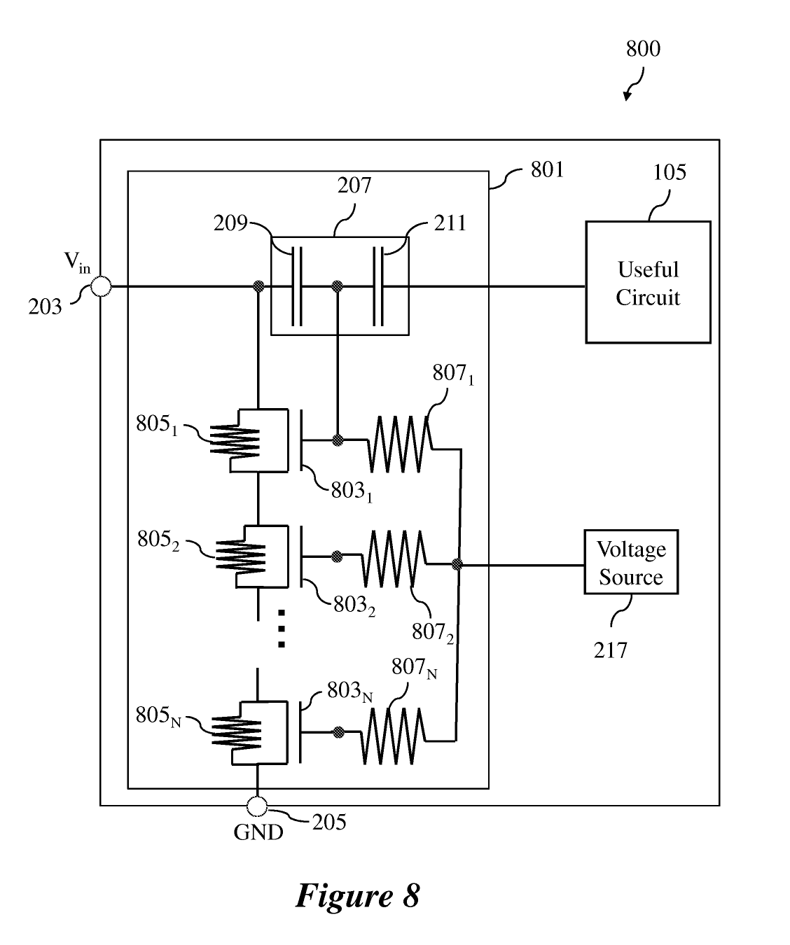

FIG. 8 illustrates an integrated circuit 800 having an embodiment ESD protection circuit 801 in which a clamping voltage of the ESD protection circuit 801 is increased by implementing an ESD transistor as a stack of series coupled transistors. In some embodiments, the ESD protection circuit 801 includes a stack of series coupled transistors 803, that replaces the transistor 213 (see FIG. 2), and resistors 805, and 807ᵢ, where i=1, 2, . . . , N. In some embodiments, the transistors 803, may be FETs such as MOS transistors formed using a bulk silicon process, MOS transistors formed using an SOI process, HEMTs such as a GaAs-HEMT, or the like. In some embodiments, the transistors 803, may have similar parameters such as, for example, a gate length, a gate width, and a threshold voltage. In other embodiments, the transistors 803, may have different parameters. A first source/drain of the transistor 803₁ is coupled to the input pin 203 of the integrated circuit 800, a second source/drain of the transistor 803₁ is coupled to a first source/drain of the transistor 803₂, and a gate of the transistor 803₁ is couples to the voltage source 217 through the resistor 807₁. For each “i” greater than 1 and less than N, a first source/drain of the transistor 803ᵢ is coupled to a second source/drain of the transistor 803ᵢ₋₁, a second source/drain of the transistor 802ᵢ is couple to a first source/drain of the transistor 803ᵢ₊₁, and a gate of the transistor 803ᵢ is couples to the voltage source 217 through the resistor 807ᵢ. A first source/drain of the transistor 803_{N} is coupled to a second source/drain of the transistor 803_{N-1}, a second source/drain of the transistor 803_{N} is couple to the ground pin 205 of the integrated circuit 800, and a gate of the transistor 803_{N} is coupled to the voltage source 217 through the resistor 807_{N}. Furthermore, for each “i,” the resistor 805ᵢ is coupled between the first source/drain and the second first source/drain of the transistor 803ᵢ. The resistors 805ᵢ are used to provide a desired DC current level in the stack of transistors 803ᵢ. By varying the value of N, a clamping voltage of the ESD protection circuit 801 can be tuned. For example, by increasing the value of N the clamping voltage of the ESD protection circuit 801 can be increased. Accordingly, the value of N may be chosen based on design requirements for the ESD protection circuit 801. For example, for N=1, an ESD protection circuit similar to the ESD protection circuit 201 is obtained (see FIG. 2). During an ESD event, the ESD protection circuit 801 operates similar to the ESD protection circuit 201, described above with reference to FIG. 2.

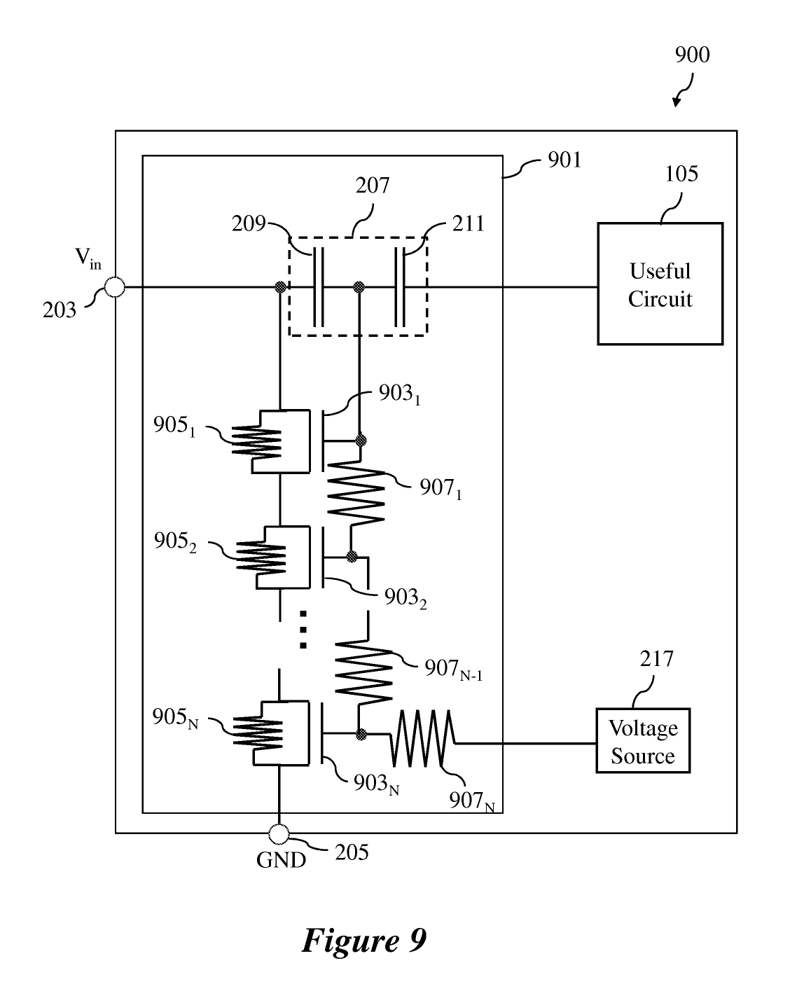

FIG. 9 illustrates an integrated circuit 900 having an embodiment ESD protection circuit 901 that is similar to ESD protection circuit 801 shown in FIG. 8, except that gate resistors 907ᵢ are coupled between the gates of adjacent transistors 903ᵢ instead of directly to the voltage source 217. Coupling the resistors 907ᵢ in this manner, allows for increasing a number of stacked transistors 903ᵢ compared to a number of stacked transistors 803ᵢ, and thus, allows for a higher clamping voltage for the ESD protection circuit 901 compared to the ESD protection circuit 801. As shown in FIG. 8, the resistors 807ᵢ are coupled in parallel between the input pin 203 and the voltage source 217. Accordingly, overall resistance of the resistors 807ᵢ may be reduced below a desired value as the number of transistors 803ᵢ and corresponding resistors 807ᵢ increases. By coupling the resistors 907ᵢ in series, overall resistance of the resistors 907ᵢ increases as the number of transistors 903, and corresponding resistors 907ᵢ increases and may have a desired value even if each of the resistors 907ᵢ has a low resistance. Furthermore, each of the resistors 907ᵢ sees a small portion of a total voltage drop, and thus, the resistors 907ᵢ have a smaller risk of overstress and/or damage. Accordingly, each of the resistors 907ᵢ may be configured to have a minimum specified size and a resistance, which may further reduce a footprint of the ESD protection circuit 901.

In some embodiments, the ESD protection circuit 901 includes a stack of series coupled transistors 903ᵢ that replaces the transistor 213 (see FIG. 2), and resistors 905ᵢ and 907ᵢ, where i=1, 2, . . . , N. In some embodiments, the transistors 903ᵢ may be FETs such as MOS transistors formed using a bulk silicon process, MOS transistors formed using an SOI process, HEMTs such as a GaAs-HEMT, or the like. In some embodiments, the transistors 903, may have similar parameters such as, for example, a gate length, a gate width, and a threshold voltage. In other embodiments, the transistors 903ᵢ may have different parameters. A first source/drain of the transistor 903₁ is coupled to the input pin 203 of the integrated circuit 900, a second source/drain of the transistor 903₁ is coupled to a first source/drain of the transistor 903₂, and a gate of the transistor 903₁ is coupled a gate of the transistor 903₂ through the resistor 907₁. For each “i” greater than 1 and less than N, a first source/drain of the transistor 903ᵢ is coupled to a second source/drain of the transistor 903ᵢ₋₁, a second source/drain of the transistor 903ᵢ is coupled to a first source/drain of the transistor 903ᵢ₊₁, and a gate of the transistor 903ᵢ is coupled to a gate of the transistor 903ᵢ₋₁ through the resistor 907ᵢ₋₁ and to a gate of the transistor 903ᵢ₊₁ through the resistor 907ᵢ. A first source/drain of the transistor 903_{N} is coupled to a second source/drain of the transistor 903_{N-1}, a second source/drain of the transistor 903_{N} is coupled to the ground pin 205 of the integrated circuit 900, and a gate of the transistor 903_{N} is coupled to a gate of the transistor 903_{N-1} through the resistor 907_{N-1} and to the voltage source 217 through the resistor 907_{N}. Furthermore, for each “i,” the resistor 905ᵢ is coupled between the first source/drain and the second first source/drain of the transistor 903ᵢ. The resistors 905ᵢ are used to provide a desired DC current level in the stack of transistors 903ᵢ. By varying the value of N, a clamping voltage of the ESD protection circuit 901 can be tuned. For example, by increasing the value of N the clamping voltage of the ESD protection circuit 901 can be increased. Accordingly, the value of N may be chosen based on design requirements for the ESD protection circuit 901. For example, for N=1, an ESD protection circuit similar to the ESD protection circuit 201 is obtained. During an ESD event, the ESD protection circuit 901 operates similar to the ESD protection circuit 201, described above with reference to FIG. 2.

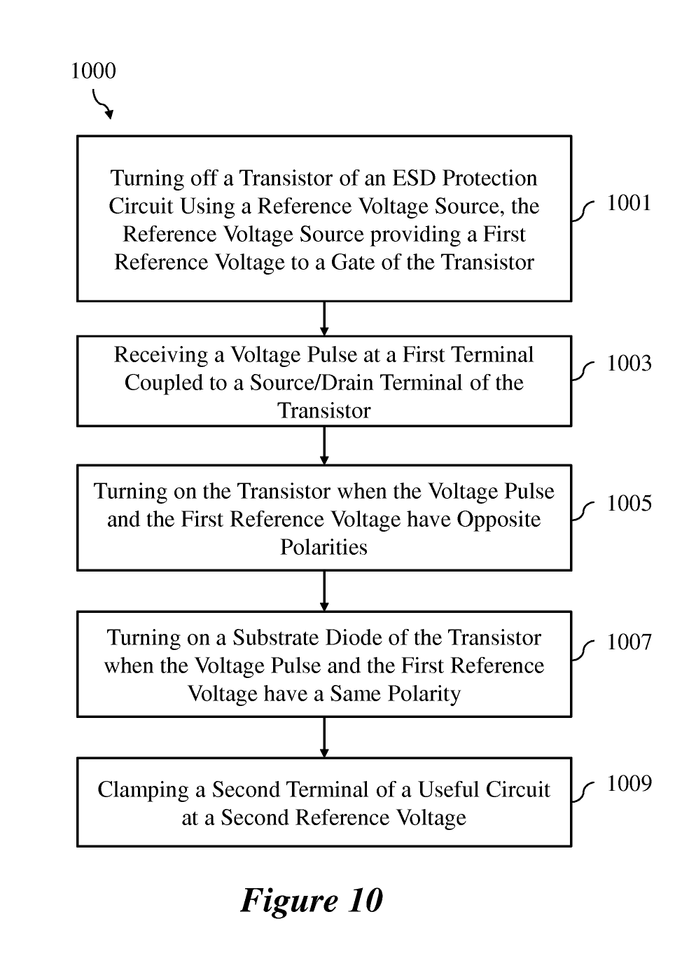

FIG. 10 illustrates a flowchart of a method 1000 of operating an ESD protection circuit in accordance with some embodiments. The method 1000 will be described with reference to the ESD protection circuit 201 (see FIG. 2). However, one of ordinary skill in the art would appreciate that methods similar to the method 1000 may be also applied to the ESD protection circuits 401 to 901. In some embodiments, the method 1000 starts with step 1001, where a first reference voltage of the reference voltage source (such as the voltage source 217 illustrate in FIG. 2) is applied to a transistor (such as the transistor 213 illustrated in FIG. 2) of the ESD protection circuit such that the first reference voltage and a threshold voltage of the transistor of the ESD circuit have opposite polarities. Accordingly, the first reference voltage causes the transistor of the ESD protection circuit to turn off. In some embodiments in which the transistor of the ESD protection circuit is an NMOS transistor, the first reference voltage has the negative polarity. In step 1003, an ESD event occurs and a voltage pulse is received at a first terminal (such as the input pin 203 illustrated in FIG. 2) coupled to source/drain terminal of the transistor. In step 1005, the transistor of the ESD protection circuit turns on when the voltage pulse and the first reference voltage have opposite polarities. A channel of the transistor starts conducting as soon as a gate voltage of the transistor reaches a threshold voltage of the transistor. In step 1007, the transistor of the ESD protection circuit remains turned off when the voltage pulse and the first reference voltage have a same polarity. However, a substrate diode of the transistor is tuned on and starts to conduct. In step 1009, an input/output terminal of a useful circuit (such as the useful circuit 105 illustrated in FIG. 2) is clamped at a second reference voltage, which is below a voltage damaging the protected circuit.

According to various embodiments described herein, advantages may include an efficient ESD protection without adversely affecting a noise performance and linearity of a useful circuit, and without adversely affecting a chip footprint. Other advantages include ability to tune a clamping voltage of an ESD protection circuit according to requirements of the useful circuit and ability to use an ESD protection circuit as a switch.

Embodiments of the present invention are summarized here. Other embodiments can also be understood form the entirety of the specification and the claims filed herein. One general aspect includes an electrostatic discharge (ESD) protection circuit including: a first transistor having a first source/drain coupled to a first input/output terminal, a second source/drain coupled to a first reference voltage terminal, and a gate coupled to a second reference voltage terminal; and a direct current (DC) blocking circuit having a first input/output node coupled to the first input/output terminal, a second input/output node configured to be coupled to a useful circuit, and a third input/output node coupled a gate of the first transistor. Other embodiments of this aspect include corresponding circuits and systems configured to perform the various actions of the methods.

Implementations may include one or more of the following features. The ESD protection circuit where the DC blocking circuit includes: a first capacitor coupled between the first input/output node and the third input/output node; and a second capacitor coupled between the third input/output node and the second input/output node. The ESD protection circuit where the DC blocking circuit includes: a second transistor having a first source/drain coupled to the first input/output terminal and a gate coupled to the second reference voltage terminal; and a first capacitor coupled between a second source/drain of the second transistor and the second input/output node. The ESD protection circuit further including a second capacitor coupled between the first source/drain of the second transistor and the second source/drain of the second transistor. The ESD protection circuit where the first reference voltage terminal is coupled to the ground. The ESD protection circuit further including a voltage source having an output coupled to the second reference voltage terminal, the voltage source configured to provide a voltage having an opposite polarity of a threshold voltage of the first transistor. The ESD protection circuit further including a resistor coupled between the gate of the first transistor and the second reference voltage terminal. The ESD protection circuit further including a second transistor having a first source/drain coupled to the second source/drain of the first transistor, a second source/drain coupled to the first reference voltage terminal, and a gate coupled to the second reference voltage terminal. The ESD protection circuit further including the useful circuit.

A further general aspect includes an integrated circuit including: an input pad; a useful circuit; and an electrostatic discharge (ESD) protection circuit coupled between the input pad and an input/output terminal of the useful circuit. The ESD protection circuit including: a direct current (DC) blocking circuit coupled between the input pad and the input/output terminal of the useful circuit, and a first transistor having a first source/drain coupled to the input pad, a second source/drain coupled to the ground, and a gate coupled to the dc blocking circuit at a first node. The integrated circuit further including a reference voltage source coupled to the gate of the first transistor at the first node, the reference voltage source providing a reference voltage to turn the first transistor off.

Implementations may include one or more of the following features. The integrated circuit where the reference voltage source is configured to provide a voltage having an opposite polarity of a threshold voltage of the first transistor. The integrated circuit where the ESD protection circuit further includes a second transistor having a first source/drain coupled to the second source/drain of the first transistor, a second source/drain coupled to the ground, and a gate coupled to the reference voltage source. The integrated circuit where the DC blocking circuit includes: a first capacitor coupled between the input pad and the first node; and a second capacitor coupled between the first node and the input/output terminal of the useful circuit. The integrated circuit where the DC blocking circuit includes: a second transistor having a first source/drain coupled to the input pad and a gate coupled to the reference voltage source; and a capacitor coupled between a second source/drain of the second transistor and the input/output terminal of the useful circuit. The integrated circuit where the ESD protection circuit further includes a plurality of transistors coupled in series between the first transistor and the ground, a gate of each transistor of the plurality of transistors being coupled to the reference voltage source. The integrated circuit where the ESD protection circuit further includes a plurality of resistors, each resistor of the plurality of resistors being coupled between a corresponding gate of a corresponding transistor of the plurality of transistors and the reference voltage source. The integrated circuit where the ESD protection circuit further includes a plurality of resistors coupled in series between the input pad and the reference voltage source, each resistor of the plurality of resistors being coupled between gates of adjacent transistors of the plurality of transistors. The integrated circuit further including a resistor coupled between the gate of the first transistor and the reference voltage source. The integrated circuit where the first transistor is an n-type metal-oxide semiconductor field effect transistor. The integrated circuit where the reference voltage source includes a charge pump.

A further general aspect includes a method including: applying a first voltage between a gate terminal and a first source/drain terminal of a first transistor, the first transistor having the first source/drain terminal coupled to a first power supply node and a second source/drain terminal coupled to an input pad of an integrated circuit, where the first voltage an a threshold voltage of the first transistor have opposite polarities; receiving an ESD pulse of a first polarity at the input pad of the integrated circuit; and turning-on the first transistor upon receipt of the ESD pulse of the first polarity, turning-on the first transistor including capacitively coupling the ESD pulse of the first polarity from the input pad of the integrated circuit to the gate terminal of the first transistor.

Implementations may include one or more of the following features. The method further including: applying an AC voltage to the input pad of the integrated circuit; and capacitively coupling the AC voltage from the input pad to an input of a useful circuit disposed on the integrated circuit. The method where: capacitively coupling the ESD pulse of the first polarity includes coupling via a first capacitor coupled between the input pad and the gate terminal of the first transistor; and capacitively coupling the AC voltage includes coupling via the first capacitor, and via a second capacitor coupled between the gate terminal of the first transistor and the input of the useful circuit. The method further including: receiving an ESD pulse of a second polarity opposite the first polarity at the input pad of the integrated circuit; and clamping the input pad to the first power supply node via a bulk diode of the first transistor.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An electrostatic discharge (ESD) protection circuit comprising:
a first transistor having a first source/drain coupled to a first input/output terminal, a second source/drain coupled to a first reference voltage terminal, and a gate coupled to a second reference voltage terminal; and
a direct current (DC) blocking circuit having a first input/output node coupled to the first input/output terminal, a second input/output node configured to be coupled to a useful circuit, and a third input/output node coupled a gate of the first transistor.

2. The ESD protection circuit of claim 1, wherein the DC blocking circuit comprises:
a first capacitor coupled between the first input/output node and the third input/output node; and
a second capacitor coupled between the third input/output node and the second input/output node.

3. The ESD protection circuit of claim 1, wherein the DC blocking circuit comprises:
a second transistor having a first source/drain coupled to the first input/output terminal and a gate coupled to the second reference voltage terminal; and
a first capacitor coupled between a second source/drain of the second transistor and the second input/output node.

4. The ESD protection circuit of claim 3, further comprising a second capacitor coupled between the first source/drain of the second transistor and the second source/drain of the second transistor.

5. The ESD protection circuit of claim 1, wherein the first reference voltage terminal is coupled to the ground.

6. The ESD protection circuit of claim 1, further comprising a voltage source having an output coupled to the second reference voltage terminal, the voltage source configured to provide a voltage having an opposite polarity of a threshold voltage of the first transistor.

7. The ESD protection circuit of claim 1, further comprising a resistor coupled between the gate of the first transistor and the second reference voltage terminal.

8. The ESD protection circuit of claim 1, further comprising a second transistor having a first source/drain coupled to the second source/drain of the first transistor, a second source/drain coupled to the first reference voltage terminal, and a gate coupled to the second reference voltage terminal.

9. The ESD protection circuit of claim 1, further comprising the useful circuit.

10. An integrated circuit comprising:
an input pad;
a useful circuit; and
an electrostatic discharge (ESD) protection circuit coupled between the input pad and an input/output terminal of the useful circuit, the ESD protection circuit comprising
a direct current (DC) blocking circuit coupled between the input pad and the input/output terminal of the useful circuit, and
a first transistor having a first source/drain coupled to the input pad, a second source/drain coupled to the ground, and a gate coupled to the DC blocking circuit at a first node; and
a reference voltage source coupled to the gate of the first transistor at the first node, the reference voltage source providing a reference voltage to turn the first transistor off.

11. The circuit of claim 10, wherein the reference voltage source is configured to provide a voltage having an opposite polarity of a threshold voltage of the first transistor.

12. The circuit of claim 10, wherein the ESD protection circuit further comprises a second transistor having a first source/drain coupled to the second source/drain of the first transistor, a second source/drain coupled to the ground, and a gate coupled to the reference voltage source.

13. The circuit of claim 10, wherein the DC blocking circuit comprises:
a first capacitor coupled between the input pad and the first node; and
a second capacitor coupled between the first node and the input/output terminal of the useful circuit.

14. The circuit of claim 10, wherein the DC blocking circuit comprises:
a second transistor having a first source/drain coupled to the input pad and a gate coupled to the reference voltage source; and
a capacitor coupled between a second source/drain of the second transistor and the input/output terminal of the useful circuit.

15. The circuit of claim 10, wherein the ESD protection circuit further comprises a plurality of transistors coupled in series between the first transistor and the ground, a gate of each transistor of the plurality of transistors being coupled to the reference voltage source.

16. The circuit of claim 15, wherein the ESD protection circuit further comprises a plurality of resistors, each resistor of the plurality of resistors being coupled between a corresponding gate of a corresponding transistor of the plurality of transistors and the reference voltage source.

17. The circuit of claim 15, wherein the ESD protection circuit further comprises a plurality of resistors coupled in series between the input pad and the reference voltage source, each resistor of the plurality of resistors being coupled between gates of adjacent transistors of the plurality of transistors.

18. The circuit of claim 10, further comprising a resistor coupled between the gate of the first transistor and the reference voltage source.

19. The circuit of claim 10, wherein the first transistor is an N-type metal-oxide semiconductor field effect transistor.

20. The circuit of claim 10, wherein the reference voltage source comprises a charge pump.

21. A method comprising:
applying a first voltage between a gate terminal and a first source/drain terminal of a first transistor, the first transistor having the first source/drain terminal coupled to a first power supply node and a second source/drain terminal coupled to an input pad of an integrated circuit, wherein the first voltage an a threshold voltage of the first transistor have opposite polarities;
receiving an ESD pulse of a first polarity at the input pad of the integrated circuit; and
turning-on the first transistor upon receipt of the ESD pulse of the first polarity, turning-on the first transistor comprising capacitively coupling the ESD pulse of the first polarity from the input pad of the integrated circuit to the gate terminal of the first transistor.

22. The method of claim 21, further comprising:
applying an AC voltage to the input pad of the integrated circuit; and
capacitively coupling the AC voltage from the input pad to an input of a useful circuit disposed on the integrated circuit.

23. The method of claim 22, wherein:
capacitively coupling the ESD pulse of the first polarity comprises coupling via a first capacitor coupled between the input pad and the gate terminal of the first transistor; and
capacitively coupling the AC voltage comprises coupling via the first capacitor, and via a second capacitor coupled between the gate terminal of the first transistor and the input of the useful circuit.

24. The method of claim 21, further comprising:
receiving an ESD pulse of a second polarity opposite the first polarity at the input pad of the integrated circuit; and
clamping the input pad to the first power supply node via a bulk diode of the first transistor.
